(19) United States
(12) Patent Application Publication
(10) Pub. No.: US 2008/0061829 A1
(43) Pub. Date: Mar. 13, 2008

(54) Methods and apparatus for reducing duty cycle distortion in a multiple-stage inverter

(75) Inventor: Chiaki Takano, Austin, TX (US)

Correspondence Address: KAPLAN GILMAN GIBSON & DERNIER L.L.P., 900 ROUTE 9 NORTH, WOODBRIDGE, NJ, 07095, US

(73) Assignee: Sony Computer Entertainment Inc., Tokyo (JP)

(21) Appl. No.: 11/509,531

(22) Filed: Aug. 24, 2006

(51) Int. Cl. H03K 19/094

(52) U.S. Cl. 326/83

(57) ABSTRACT

An apparatus and method are disclosed which may include a multiple-stage inverter circuit, having at least first, second, and third stages, wherein a ratio (Rₘ₋₍ₘ₋₁₎) between a size of a given one of said stages “m” to a size of a stage “m-1” immediately preceding stage m is less than N^{(1/L-1)}, where “L” equals the number of stages in said inverter circuit and “N” equals the size ratio between the last and first stages of the inverter circuit.

### BACKGROUND OF THE INVENTION

The present invention relates to reducing duty cycle distortion in inverter circuits. In LSI (Large Scale Integration) integrated circuits, clock signals are commonly propagated from one or more clock signal sources throughout an entire chip. A distribution network used for such propagation commonly includes three-stage inverters, which are used because they have smaller input capacitance and greater fan-out than single-stage inverters.

Existing three-stage inverters commonly incorporate FETs (Field Effect Transistors) of different sizes within an inverter circuit wherein the size ratio between successive FETs is constant within the inverter circuit. For example, under this approach, a first stage may employ a FET of size “1” and the third stage FET may be of size “N”. Specific linear dimensions are omitted for the sake of simplicity in this discussion. In this exemplary inverter circuit, the second stage FET would have a size of Sqrt (N) (Square root of “N”) using the conventional approach. This arrangement is convenient as it enables providing voltage wave forms having approximately the same slew rate at the inputs of both the second and third stages of the three-stage inverter circuit. However, this relative magnitude of FET sizes does not optimize all of the inverter circuit characteristics. In particular, duty-cycle distortion may not be optimum when employing the “constant ratio” approach for FET sizes.

Moreover, imperfections in PFET (Positive Channel Field Effect Transistor) and NFET (Negative Channel Field Effect Transistor) performance may cause actual duty cycle distortion to deviate from that predicted using ideal values for NFET and PFET performance. Herein, the term “performance” refers to the amount of current driven by the FET when in the “ON” state.

Accordingly, there is a need in the art for a selection of FET sizes that improves the duty-cycle distortion of inverter circuits and which reduces the sensitivity of duty-cycle distortion to FET performance variation.

### SUMMARY OF THE INVENTION

According to one aspect, the invention provides an apparatus that may include a multiple-stage inverter circuit, having at least first, second, and third stages, wherein a ratio (Rₘ₋₍ₘ₋₁₎) between a size of a given one of the stages identified as “m” to a size of a stage identified as “m−1”, immediately preceding stage m, is less than N^{(1/L-1)}, where “L” equals the number of stages in the inverter circuit and “N” equals the size ratio between the last and first stages of the inverter circuit.

According to another aspect, the invention provides an apparatus that may include a three-stage FET inverter circuit, the three stages having respective sizes, wherein the ratio between the second-stage size and the first-stage size, R₂₋₁, is less than N^{1/2}₁ where “N” equals the size ratio between the third stage and the first stage of said inverter circuit.

Other aspects, features, advantages, etc. will become apparent to one skilled in the art when the description of the preferred embodiments of the invention herein is taken in conjunction with the accompanying drawings.

### BRIEF DESCRIPTION OF THE DRAWINGS

For the purposes of illustrating the various aspects of the invention, there are shown in the drawings forms that are presently preferred, it being understood, however, that the invention is not limited to the precise arrangements and instrumentalities shown.

FIG. 1 is a schematic diagram of a three-stage inverter circuit in accordance with one or more embodiments of the present invention;

FIG. 2 includes plots of duty cycle distortion versus second-stage to first-stage FET size ratio for various values of PFET performance, for an inverter having a value of N=8, in accordance with one or more embodiments of the present invention;

FIG. 3 includes plots of duty cycle distortion versus second-stage to first-stage FET size ratio for various values of NFET performance, for a value of N=8, in accordance with one or more embodiments of the present invention;

FIG. 4 is a plot of delay time versus second stage to first stage FET size ratio, for an inverter having N=8, in accordance with one or more embodiments of the present invention;

FIG. 5 is a plot of slew rate versus second stage to first stage FET size ratio, for an inverter having N=8, in accordance with one or more embodiments of the present invention;

FIG. 6 includes plots of duty cycle distortion versus second-stage to first-stage FET size ratio for various values of PFET performance, for an inverter having a value of N=16, in accordance with one or more embodiments of the present invention;

FIG. 7 includes plots of duty cycle distortion versus second-stage to first-stage FET size ratio for various values of NFET performance, for a value of N=16, in accordance with one or more embodiments of the present invention;

FIG. 8 is a plot of delay time versus second stage to first stage FET size ratio, for an inverter with N=16, in accordance with one or more embodiments of the present invention; and

FIG. 9 is a plot of slew rate versus second stage to first stage FET size ratio, for an inverter with N=16, in accordance with one or more embodiments of the present invention.

### DETAILED DESCRIPTION OF THE PREFERRED EMBODIMENTS

A general presentation of the concepts pertinent herein is presented to aid in describing one or more embodiments of the present invention. For an inverter having “L” stages, and having a size ratio of “N” between the last stage and the first stage thereof, existing systems typically include a size ratio between successive stages established according to the following formula:

Rₘ₋₍ₘ₋₁₎=N^{(1/L-1))},

where “m” represents a given stage number within the inverter, and “m−1” represents the stage immediately preceding the given stage number.

In one or more embodiments of the present invention, it is proposed to change the size ratio between at least two adjacent inverter stages from that conventionally practiced. Specifically, the proposed “m” stage to “m−1” stage size ratio may be represented by the relationship:

### Rₘ₋₍ₘ₋₁₎<N^{(1/L-1)}.

The foregoing relationship is proposed because simulation results indicate that changing the relationship as indicated may beneficially reduce duty cycle distortion arising from clock signal propagation through an inverter circuit.

It is noted that slew rate and delay time are parameters of inverter circuits to be kept in mind while optimizing the parameter of duty cycle distortion. Accordingly, the optimization of inverter stage size ratios to minimize duty-cycle distortion is preferably conducted subject to the constraint that the parameters of slew rate and delay time be kept within reasonable bounds.

### Three-Stage Inverters

We turn now from the general case to the more specific case of three-stage inverters. Simplifying the formula provided above, for a three-stage inverter, conventional size ratios between the second stage and first stage and that between the third stage and the second stage are provided by the formula R₂₋₁=R₃₋₂=N^{1/2}. In the foregoing, R₂₋₁ is the size ratio between the second and first stages, and R₃₋₂ is the size ratio between the third and second stages.

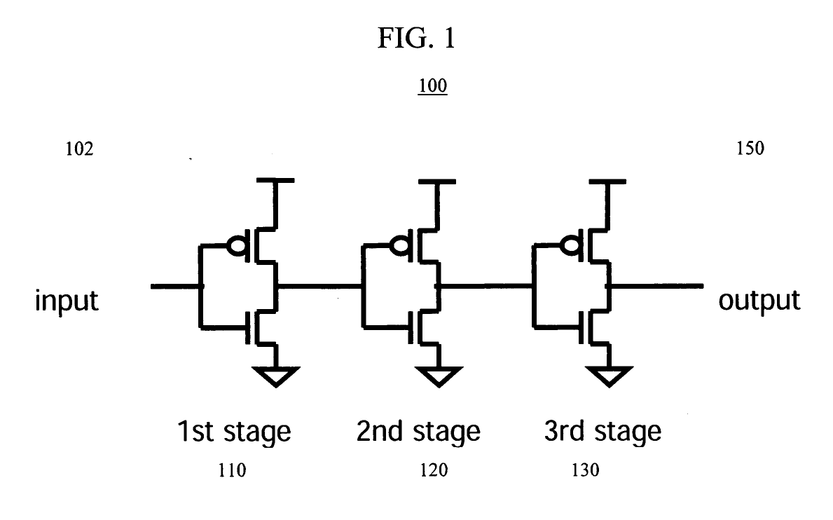

Recalling the previously mentioned simulation results, it is noted here, specifically with respect to three-stage inverters, that simulation results have indicated that duty cycle distortion improves where R₂₋₁ is less than N^{1/2}. Accordingly, attention is directed to FIG. 1 for a discussion of a specific three-stage inverter 100.

FIG. 1 is a schematic diagram of a three-stage inverter 100 circuit in accordance with one or more embodiments of the present invention. Inverter 100 may include input 102, first stage 110, second stage 120, third stage 130, and output 150.

In one or more embodiments, the ratio of the FET size of the third stage 130 to that of the first stage 110 is equal to “N.” While one or more embodiments of the present invention are described as including FETs, the invention is not limited to the use of this type of transistor. In some cases, the term “size ratio” is applied to the ratio of sizes of FETs in different stages of inverter circuit 100. However, the term “size ratio” is also applied more generally to a ratio of sizes of successive stages of inverter circuits, as the present invention is not limited to the use of FETs.

In accordance with the goal of determining a desired value of R₂₋₁, the following discussion concerns simulation results using a range of successive stage FET size ratios and FETs having differing performance criteria. While the simulation results discussed below are for inverters employing FETS, the present invention is not limited to the use of FETs.

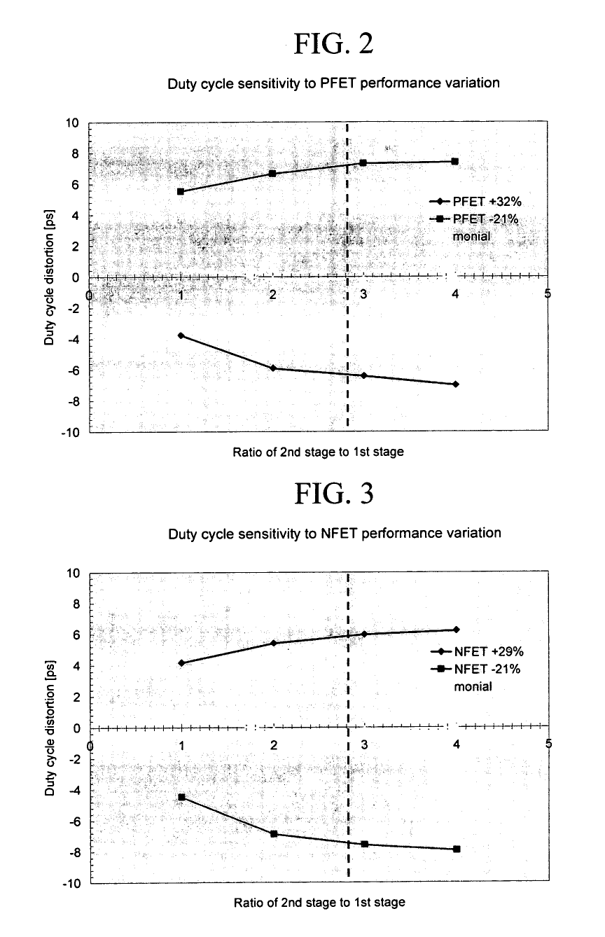

FIGS. 2-5 and 6-9 pertain to simulation results for a three-stage inverter having values of N=8, and N=16, respectively. In the following discussion, similar graphs of inverter properties for the two “N” values are discussed together.

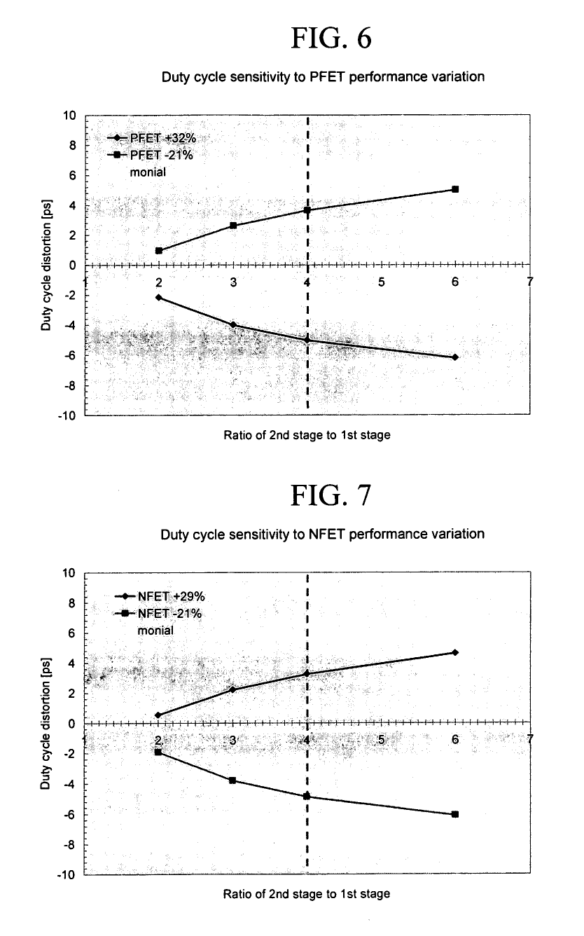

FIG. 2 includes plots of duty cycle distortion versus second-stage to first-stage size ratio for various values of PFET performance, for an inverter having a value of N=8 (in this case, the ratio of third stage size to first stage size), in accordance with one or more embodiments of the present invention. FIG. 6 includes the plots similar to those of FIG. 2, but for inverters with an N value of 16. It will be appreciated that the concepts discussed in the following apply to values of N other than 8 or 16.

In connection with FIGS. 2 and 6 (and other pertinent FIGS herein), a positive value of duty cycle distortion corresponds to a widening of a clock signal pulse width. Conversely, a negative value of duty cycle distortion corresponds to a narrowing of a clock signal pulse width.

FIG. 2 includes three plot lines and a dashed vertical line, which are described in the following. The uppermost plot, which has square highlighted data points, shows the duty cycle distortion as a function of R₂₋₁ when using a PFET with a performance level 21% lower than the nominal value. The center plot has triangular highlighted data points and shows the duty cycle distortion as a function of R₂₋₁ value when using a PFET with nominal, or ideal, performance. The lower plot has diamond-shaped highlighted data points and shows the duty cycle distortion as a function of R₂₋₁ when using a PFET with a performance level 32% higher than the nominal value. The NFETs in all three plots are at nominal performance levels. The foregoing description is also applicable to FIG. 6.

The vertical dashed line shows the value R₂₋₁ commonly employed in existing inverter circuits. In the plot of FIG. 2, this line is located at a value of:

R₂₋₁=Sqrt (8)≈2.828. In the plot of FIG. 6, this line is located at a value of R₂₋₁=Sqrt (16)=4.

Gate widths, in linear units, which may be employed with one or more embodiments of the present invention are provided below. It is noted that gate widths are a function of the LSI process technology generation employed, such as but not limited to 90 nm (nanometers), 65 nm, and 45 nm. Accordingly, the present invention is not limited the specific gate widths listed below. The abbreviation “um” below refers to micrometers.

### For FIGS. 2-5

2^{nd} Stage to 1^{st} Stage
Size Ratio

| | 1 | 2 | 3 | 4 |
|---|---|---|---|---|
| PFET gate width of 2^{nd} | 18.62 | 37.24 | 55.86 | 74.48 |
| stage inverter [um] | | | | |
| NFET gate width of 2^{nd} | 9.8 | 19.6 | 29.4 | 39.2 |
| stage inverter [um] | | | | |

### For FIGS. 6-10

2^{nd} Stage to 1^{st} Stage
Size Ratio

| | 2 | 3 | 4 | 6 |
|---|---|---|---|---|
| PFET gate width of 2^{nd} | 37.24 | 55.86 | 74.48 | 111.72 |
| stage inverter [um] | | | | |
| NFET gate width of 2^{nd} | 19.6 | 29.4 | 39.2 | 58.8 |
| stage inverter [um] | | | | |

In FIGS. 2 and 6, the center plot, which illustrates the performance of an ideal PFET, shows quite low duty-cycle distortion. However, as indicated earlier, this ideal PFET performance may not be representative of PFETs found in actual inverter circuits.

The upper and lower plots of both FIGS. 2 and 6 indicate that duty cycle distortion tends to improve (decline) as R₂₋₁ (represented by the horizontal axis of the graph) declines from the commonly employed value of Sqrt (N), which is indicated by the vertical dashed lines.

Next, in FIGS. 3 and 7, which are directed to simulation data for N values of 8 and 16, respectively, plots similar to those above are discussed, but using NFET performance as the distinguishing factor between the different plot lines.

FIG. 3 includes plots of duty cycle distortion versus second-stage to first-stage size ratio for various values of NFET performance, for a value of N=8, in accordance with one or more embodiments of the present invention. FIG. 7 includes plots of values analogous to those of FIG. 3, but for inverters having an N value of 16.

Three plots are shown in FIG. 3, which are described in the following. The lower plot has square highlighted data points and shows the duty cycle distortion as a function R₂₋₁ value when using an NFET with a performance level 21% lower than the nominal value. The center plot has triangular highlighted data points and shows the duty cycle distortion as a function of R₂₋₁ value when using an NFET with nominal, or ideal, performance. The upper plot has diamond-shaped highlighted data points and shows the duty cycle distortion as a function of R₂₋₁ value when using an NFET with a performance level 29% higher than the nominal value. PFETs in all tree plots are at nominal performance levels. The foregoing description is applicable to FIG. 7 as well as FIG. 3. As with FIGS. 2 and 6, both FIGS. 3 and 7 include respective dashed vertical lines at the respective R₂₋₁ values of Sqrt (N).

In FIGS. 3 and 7, the center plot, which illustrates the performance of an ideal NFET, shows quite low duty cycle distortion. However, as indicated earlier, this ideal NFET performance may not be representative of NFETs found in actual inverter circuits.

The upper and lower plots of FIGS. 3 and 7 indicate that duty-cycle distortion tends to improve (decline) as R₂₋₁ (represented by the horizontal axis of the graph) declines from the commonly employed value of Sqrt (N), which value is Sqrt (8) in FIG. 3, and Sqrt (16)=4 in FIG. 7.

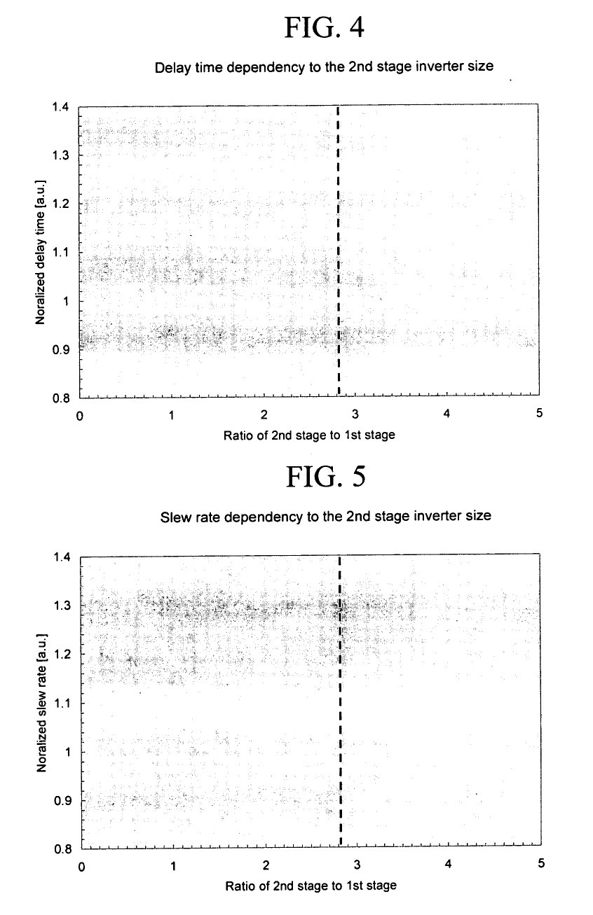

It remains to determine how the values of R₂₋₁ indicated as desirable from the standpoint of duty-cycle distortion by the plots of FIGS. 2-3 and 6-7 impact the parameters of delay time and slew rate. This is explored in connection with FIGS. 4-5 and 8-9 in the following.

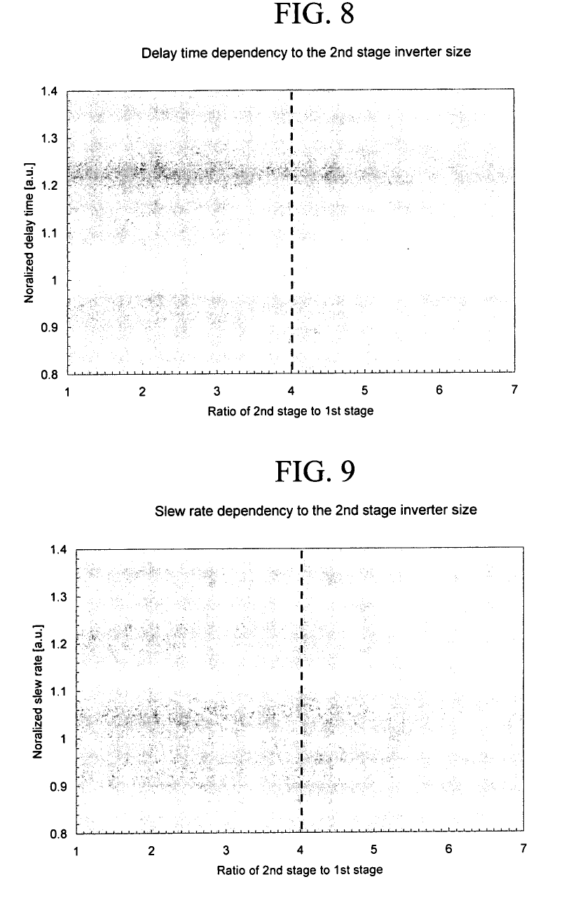

FIG. 4 is a plot of delay time versus second stage to first stage size ratio, for an inverter with N=8, in accordance with one or more embodiments of the present invention. FIG. 5 is a plot of slew rate versus second stage to first stage size ratio, for an inverter with N=8, in accordance with one or more embodiments of the present invention. FIGS. 8 and 9 present plots analogous to those of FIGS. 4 and 5, respectively, but for an “N” value of 16.

FIGS. 4 and 5 indicate that the delay time and slew rate, respectively, of inverter circuit 100 degrade as R₂₋₁ decreases. However, the delay time and slew rate remain within a fairly tight range for values of R₂₋₁ between 2 and 4.

In the case of N=16, the delay time and slew rate for which are illustrated in FIGS. 8 and 9, respectively, the delay time and slew rate also degrade as R₂₋₁ decreases. However, the delay time and slew rate remain within a fairly tight range for values of R₂₋₁ between 3 and 5.

From the above simulated results for N=8, it appears that selecting an R₂₋₁ value of about 2 provides better (lower) duty cycle distortion than the Sqrt (8) value commonly employed in existing inverter circuits. Moreover, this value of R₂₋₁ prevents the significant degradation (increase) in delay time and slew rate resulting from still lower values of R₂₋₁.

A parallel observation may be made regarding the results for the case where N=16. The results indicate that for N=16, selecting an R₂₋₁ value of about 3 provides better (lower) duty cycle distortion than using the value of Sqrt (16)=4 commonly employed in existing inverter circuits. Moreover, this value of R₂₋₁ prevents significant degradation (increase) in delay time and slew rate which result from the use of R₂₋₁ values significantly lower than 3.

### Ranges of Ratio Values in Various Embodiments

The simulated results discussed above indicate that values of R₂₋₁ lower than the conventional value of N^{1/(L-1)} for the general case of an inverter circuit with “L” stages and more particularly, lower than Sqrt (L) or L^{1/2} for three-stage inverters may provide desired performance characteristics for inverter circuits. The above results indicate that R₂₋₁ values of 2 and 3 provide beneficial results for three-stage inverters having N values of 8 and 16, respectively. However, it remains to describe the ranges of R₂₋₁ values contemplated for use in one or more embodiments of the present invention.

The ranges of R₂₋₁ values contemplated for use in one or more embodiments of the present invention may be expressed multiplicatively and/or exponentially. For example, for the case where N=8, the preferred R₂₋₁ value of 2 is about 30% lower than the conventional value of Sqrt (8) of 2.828. When N=16, the preferred R₂₋₁ value of 3 is 25% below the conventional value of Sqrt (16)=4. Thus, the desired ranges of preferred R₂₋₁ value may be expressed multiplicatively, or in other words, as percentages of the value arrived at using the conventional formula described earlier herein.

For the purpose of the following discussion of preferred ranges, the “conventional value” for size ratio between successive stages of an inverter is considered to be N^{(1/L-1)}.

Thus, in one or more embodiments, Rₘ₋₍ₘ₋₁₎ (size ratio between two successive stages in an inverter circuit) may be 5% or more lower than the conventional value. In other embodiments, Rₘ₋₍ₘ₋₁₎ may be 10% or more lower than the conventional value. In still other embodiments, Rₘ₋₍ₘ₋₁₎ may be 20% or more lower than the conventional value. In still other embodiments, Rₘ₋₍ₘ₋₁₎ may be 25% or more lower than the conventional value. In still other embodiments, Rₘ₋₍ₘ₋₁₎ may be between 25% and 35% lower than the conventional value.

We turn now to preferred ranges of R₂₋₁ as expressed in terms of an exponent value to which N may be raised, for a three-stage inverter circuit. It is noted that the conventional value of such an exponent for a three-stage inverter circuit is 0.5, since the conventional value of R₂₋₁ is N^{1/2}. It is noted that for a preferred R₂₋₁ value of 2 for the case where N=8, the applicable exponent value is 0.333. And for a preferred R₂₋₁ value of 3, for N=16, the exponent value is 0.39.

Thus, in one or more embodiments, the exponent value to which N may be raised may be less than 0.5. In one or more other embodiments the exponent value may be between 0.1 and 0.45. In still other embodiments, the exponent value may be between 0.2 and 0.4. In still other embodiments, the exponent value may be between 0.25 and 0.35. In still other embodiments, the exponent value may be between 0.3 and 0.4.

The principles discussed above are not limited to inverter circuits having values of N of 8 or 16, but may be applied to inverter circuits having any permissible value of N, where “N” may be any positive real number.

Lower duty-cycle distortion attained by the system and method described above may result in improved clock signal quality. This improved clock signal quality may provide the benefit that a given clock frequency may require a lower supply voltage and correspondingly lower power consumption. Alternatively, a higher clock frequency could be employed while using a given power consumption level.

It is noted that the methods and apparatus described thus far and/or described later in this document may be achieved utilizing any of the known technologies, such as standard digital circuitry, analog circuitry, any of the known processors that are operable to execute software and/or firmware programs, programmable digital devices or systems, programmable array logic devices, or any combination of the above. One or more embodiments of the invention may also be embodied in a software program for storage in a suitable storage medium and execution by a processing unit.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. An apparatus, comprising:
a multiple-stage inverter circuit, having at least first, second, and third stages, wherein a ratio (Rₘ₋₍ₘ₋₁₎) between a size of a given one of said stages “m” to a size of a stage “m−1” immediately preceding said stage m is less than N^{(1/L-1)},
where “L” equals the number of stages in said inverter circuit and “N” equals the size ratio between the last and first stages of the inverter circuit.

2. The apparatus of claim 1 wherein Rₘ₋₍ₘ₋₁₎ is at least 5% less than N^{(1/(L-1))}.

3. The apparatus of claim 1 wherein Rₘ₋₍ₘ₋₁₎ is at least 10% less than N^{(1/(L-1))}.

4. The apparatus of claim 1 wherein Rₘ₋₍ₘ₋₁₎ is at least 20% less than N^{(1/(L-1))}.

5. The apparatus of claim 1 wherein Rₘ₋₍ₘ₋₁₎ is at least 25% less than N^{(1/(L-1))}.

6. The apparatus of claim 1 wherein Rₘ₋₍ₘ₋₁₎ is between 25% and 35% less than N^{(1/(L-1))}.

7. The apparatus of claim 1 wherein said stages are Field Effect Transistor (FET) stages.

8. The apparatus of claim 1 wherein said inverter circuit is a three-stage inverter circuit, wherein N is about 8, and wherein a ratio of the second-stage size to the first-stage size (R₂₋₁) is about 2.

9. An apparatus, comprising:
a three-stage FET inverter circuit, the three stages having respective sizes,
wherein the ratio between the second-stage size and the first-stage size, R₂₋₁, is less than N^{1/2}, where “N” equals the size ratio between the third stage and the first stage of said inverter circuit.

10. The apparatus of claim 9 wherein N is about 8 and R₂₋₁ is about 2.

11. The apparatus of claim 9 wherein N is about 8 and R₂₋₁ is within about 10% of 2.

12. The apparatus of claim 9 wherein N is about 16 and R₂₋₁ is about 3.

13. The apparatus of claim 9 wherein N is about 16 and R₂₋₁ is within 10% of 3.

14. The apparatus of claim 9 wherein R₂₋₁ is equal to N raised to a power between 0.1 and 0.45.

15. The apparatus of claim 9 wherein R₂₋₁ is equal to N raised to a power between 0.2 and 0.4.

16. The apparatus of claim 9 wherein R₂₋₁ is equal to N raised to a power between 0.25 and 0.35.

17. The apparatus of claim 9 wherein R₂₋₁ is equal to N raised to a power between 0.3 and 0.4.

18. A method, comprising:
providing a multiple-stage inverter circuit, having at least first, second, and third stages, wherein a ratio (Rₘ₋₍ₘ₋₁₎) between a size of a given one of said stages “m” to a size of a stage “m−1” immediately preceding said stage m is less than N^{(1/L-1)},
where “L” equals the number of stages in said inverter circuit and “N” equals the size ratio between the last and first stages of the inverter circuit.
